(19) United States
(12) Patent Application Publication
(10) Pub. No.: US 2015/0311702 A1
(43) Pub. Date: Oct. 29, 2015

(54) SAFE POWER SOCKET AND POWER EXTENSION DEVICE HAVING THE SAME

(71) Applicant: CERAMATE TECHNICAL CO., LTD., New Taipei City (TW)

(72) Inventor: Hsun-Hua CHEN, New Taipei City (TW)

(73) Assignee: CERAMATE TECHNICAL CO., LTD., New Taipei City (TW)

(21) Appl. No.: 14/261,244

(22) Filed: Apr. 24, 2014

(51) Int. Cl. H02H 9/04; H05K 1/18

(52) U.S. Cl. CPC H02H 9/042; H02H 9/045; H05K 1/181; H05K 2201/10022

(57) ABSTRACT

A safe power socket includes: a main body; a circuit board disposed in the main body and formed with two soldering parts; and a protection set electrically connected to the circuit board and including an insulation member, a protection wire and two electrical conduction parts respectively connected at one location and another location of the insulation member, the protection wire is formed with two end parts respectively and electrically connected to the two electrical conduction parts, and the two electrical conduction parts are respectively connected to the two soldering parts. Accordingly, the protection set having a larger force applying area can be formed for being easily and smoothly inserted in a circuit board or adhered thereon with a surface mount means, thereby greatly lowering the production difficulty and relatively increasing the yield rate, and the protection wire having a unified size can be easily manufactured.

### BACKGROUND OF THE INVENTION

1. Field of the Invention

The present invention relates to a power socket, especially to a safe power socket and a power extension device having the same which is capable of preventing a surge protection unit from being burned or bursted.

2. Description of Related Art

A general power socket is electrically connected to a plug through a power cable, when the plug is inserted for obtaining the public electricity, the electrical power of the public electricity can be extended to the power socket for providing the electrical power to an electronic product.

When in use, a surge caused by over voltage or lightning strike would pass the power socket and be transferred to the electronic product, so some electric components in the electronic product may be damaged due to the surge. As such, the skilled people in the art have developed a technology of using a surge protection unit for protecting the electronic product, but when the voltage difference exceeds the critical point of the surge protection unit, the surge protection unit would be burned or even bursted which may result in an accident.

For avoiding the above-mentioned situation, a technology of adopting a copper foil as a protection unit is developed for preventing the surge protection unit from being burned or even bursted, wherein the technology is to dispose a circuit board in a power socket, and the circuit board is formed with an electrical loop, the copper foil is electrically connected to a breaking location of the electrical loop. As such, when a surge or a large current is generated and before the surge protection unit is burned or bursted (i.e. before reaching the critical point of the surge protection unit), the surge or the large current would pass the electrical loop to melt and break the copper foil, thus the electronic product is protected and the surge protection unit is prevented from being burned or bursted.

However, for designing the copper foil being used for preventing the surge protection unit from being burned or bursted, the production of the required copper foil is extremely difficult and the unified length, width and thickness is very hard to be maintained, and the destructive test could not have the same result during the annual safety examination.

### SUMMARY OF THE INVENTION

The present invention is to provide a safe power socket and a power extension device having the same, in which a protection wire is connected to an electrical loop, so the protection wire having a unified size can be easily manufactured; moreover, the protection wire is attached on an insulation member then respectively and electrically connected to two electrical conduction parts, so a protection set having a larger force applying area can be formed, and the protection set is able to be easily and smoothly inserted in a circuit board or adhered on the circuit board with a surface mount means, thereby greatly lowering the production difficulty and relatively increasing the yield rate.

Accordingly, the present invention provides a safe power socket which includes: a main body; a circuit board disposed in the main body and formed with two soldering parts; and a protection set electrically connected to the circuit board and including an insulation member, a protection wire and two electrical conduction parts respectively connected at one location and another location of the insulation member, the protection wire is formed with two end parts respectively and electrically connected to the two electrical conduction parts, the two electrical conduction parts of the protection set are respectively connected to the two soldering parts of the circuit board.

Accordingly, the present invention provides a power extension device having a safe power socket which includes: a plug; a power cable, one end thereof is electrically connected to the plug; and a power socket, electrically connected to the other end of the power cable and including a main body, a circuit board and a protection set, the circuit board is disposed in the main body and formed with two soldering parts; the protection set is electrically connected to the circuit board, the protection set includes an insulation member, a protection wire and two electrical conduction parts respectively connected at one location and another location of the insulation member, the protection wire is formed with two end parts respectively and electrically connected to the two electrical conduction parts, the two electrical conduction parts of the protection set are respectively connected to the two soldering parts of the circuit board.

In comparison with related art, the present invention has advantageous features as following: the protection wire can be manufactured to have the unified size; and the protection set having a larger force applying area can be formed, so the protection set is able to be easily and smoothly inserted in the circuit board or adhered on the circuit board with a surface mount means, thereby greatly lowering the production difficulty and relatively increasing the yield rate.

### BRIEF DESCRIPTION OF DRAWING

FIG. 1 is a perspective view showing the power extension device according to the present invention;

FIG. 2 is a partial perspective view showing the power socket of the power extension device according to the present invention;

FIG. 3 is a perspective view showing the protection set of the power socket according to a first embodiment of the present invention;

FIG. 4 is a perspective view showing the protection set of the power socket according to a second embodiment of the present invention; and

FIG. 5 is a partial perspective view illustrating the power socket being installed with the protection set according to the second embodiment of the present invention.

### DETAILED DESCRIPTION OF THE INVENTION

Preferred embodiments of the present invention will be described with reference to the drawings.

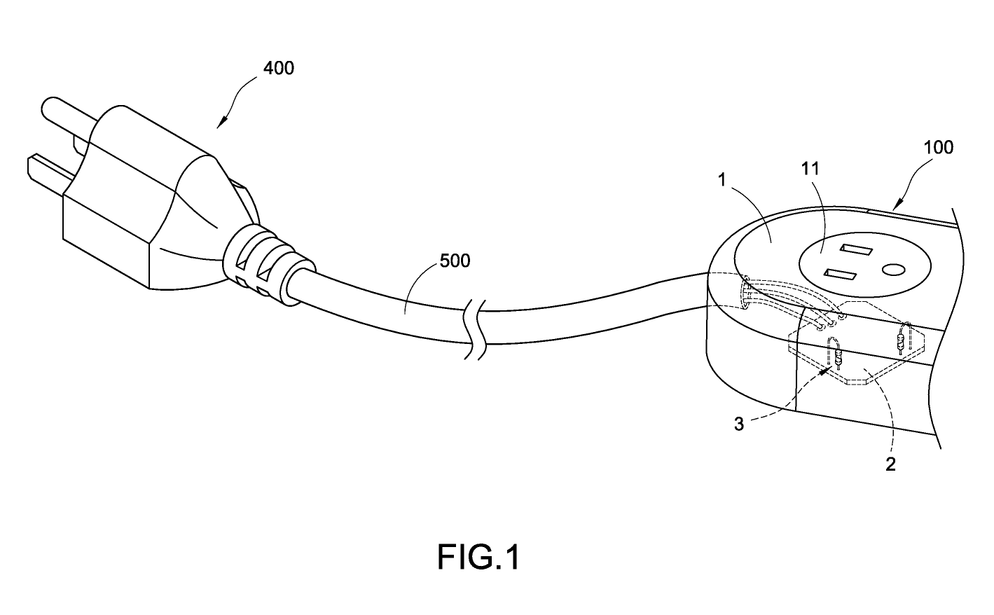

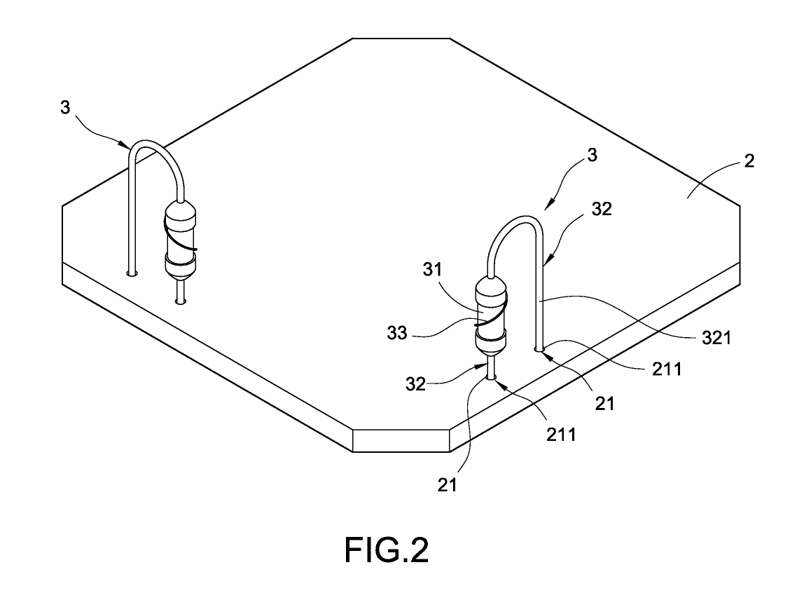

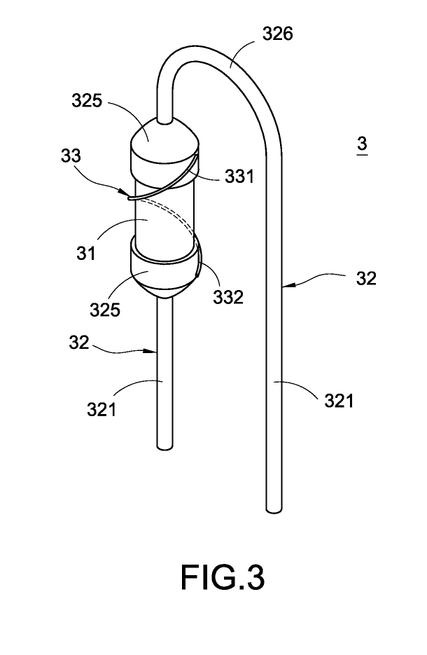

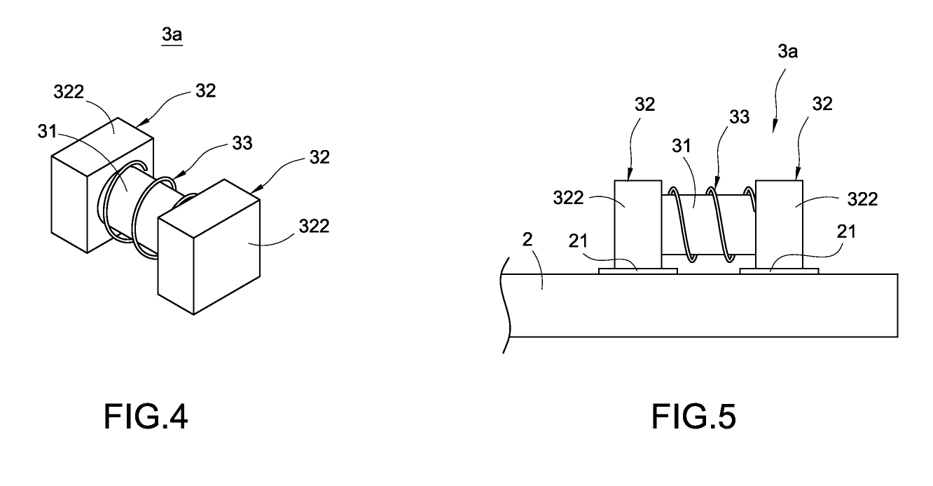

The present invention provides a safe power socket and a power extension device having the same. Please refer to FIG. 1 to FIG. 5, wherein FIG. 1 discloses the power extension device having the safe power socket 100 according to the present invention; FIG. 2 and FIG. 3 disclose a first embodiment for illustrating a protection set 3 of the power socket 100 provided by the present invention; and FIG. 4 and FIG. 5 disclose a second embodiment for illustrating a protection set 3a of the power socket 100 provided by the present invention.

As shown in FIG. 1, the power extending device provided by the present invention includes a power socket 100, a plug 400 and a power cable 500 electrically connected between the power socket 100 and the plug 400; a main body 1 of the power socket 100 can be installed with a socket unit 11 or a plurality of socket units 11, what shall be addressed is that the scope of the present invention is not limited to the quantity of the socket unit 11.

As shown from FIG. 1 to FIG. 3, which disclose a first embodiment for illustrating a protection set 3 of the power socket 100 provided by the present invention; the power socket 100 provided by the present invention includes a main body 1 (as shown in FIG. 1), a circuit board 2 (installed with a surge protection unit but not shown in figures) and a protection set 3. The circuit board 2 is disposed in the main body 1, and the circuit board 2 is formed with two sets of soldering spots (as shown in FIG. 1 and FIG. 2), hereinafter a set of soldering spots is adopted in this embodiment for illustration, each set of the soldering spots is formed with two soldering parts 21, according to this embodiment, the soldering part 21 is formed as a soldering hole 211.

The protection set 3 includes an insulation member 31, a protection wire 33 and two electrical conduction parts 32, wherein the two electrical conduction parts 32 can be formed in any status and respectively connected at one location and another location of the insulation member 31. According to this embodiment, each of the electrical conduction parts 32 is formed as an electrical conduction pin 321, the insulation member 31 is formed in a columnar status, and one end of each of the electrical conduction pins 321 is formed with an electrical conduction cap 325, the electrical conduction caps 325 of the two electrical conduction pins 321 are respectively sleeved at one end and another end of the insulation member 31 (the two ends can be correspondingly arranged as shown in figures), and one of the two electrical conduction pins 321 is further formed with a bending part 326, the bending part 326 is formed at any location defined between two ends of the electrical conduction pin 321; as such, one of the electrical conduction pins 321 is enabled to have its free end being oriented towards downward through the bending part 326 (as shown in FIG. 3), so the free end of the electrical conduction pin 321 formed with the bending part 326 is oriented towards the same direction as the free end of the other electrical conduction pin 321, thereby allowing the protection set 3 to be installed on the circuit board 2 through the free ends of the two electrical conduction pins 321 being inserted in the two soldering holes 211.

The protection wire 33 is formed with two end parts 331, 332, and the two end parts 331, 332 are respectively and electrically connected to one end (i.e. the electrical conduction cap 325) of the two electrical conduction pins 321, thereby enabling the protection wire 33 to be electrically connected between the two electrical conduction pins 321.

The protection wire 33 can be a copper wire having a relatively shorter length, two ends of the short copper wire are electrically connected to the two electrical conduction caps 325, and other portion of the short copper wire is arranged to be adjacent to the periphery of the insulation member 31, at this moment if the short copper wire is in contact with the insulation member 31, the situation of short circuit is prevented due to the insulation member 31 being made of an insulation material (such as a ceramic material); the protection wire 33 can be a copper wire having a relatively longer length, the long copper wire is firstly reeled on the insulation member 31 (as shown in FIG. 2 and FIG. 3) then two ends of the long copper wire are respectively and electrically connected to the two electrical conduction caps 325.

As shown in FIG. 2, if the protection wire 33 is solely arranged at a breaking location of an electrical loop (not shown in figures) formed on the circuit board 2 through a jumper means, the surge protection unit can still be prevented from being burned or bursted, but the manual operation for electrically connecting the protection wire 33 to the electrical loop of the circuit board 2 is very difficult, and there is no available mechanical means for solely electrically connecting the protection wire 33 to the circuit board 2 because the protection wire 33 is very thin and short and hard to be applied with an external force thereon. As such, the present invention enables the protection wire 33 to be firstly attached on the insulation member 31 then respectively and electrically connected to the two electrical conduction pins 321, thereby forming the protection set 3 having a larger force applying area as shown in FIG. 3, so the protection set 3 is able to be easily and smoothly inserted in the circuit board 2 with a manual or a mechanical means, in other words the two electrical conduction pins 321 of the protection set 3 are respectively inserted in the two soldering holes 211 of the circuit board 2.

As shown in FIG. 1, when a surge caused by over voltage or lightning strike is generated and before the surge protection unit is burned or bursted (i.e. before reaching the critical point of the surge protection unit), the protection wire 33 of the protection set 3 would be firstly melted, so the surge is prevented from passing the electrical loop which is no longer in a conducting status, and the electronic product can also be prevented from being damaged due to the surge, and an effect of preventing the surge protection unit from being burned or bursted is also provided.

As shown in FIG. 4 and FIG. 5, which disclose a second embodiment for illustrating a protection set 3a of the power socket 100 provided by the present invention, according to this embodiment, each of the electrical conduction parts 32 is formed as an electrical conduction block 322, the two electrical conduction blocks 322 are respectively sleeved at one end and another end of the insulation member 31, and the two electrical conduction blocks 322 are served to lift the insulation member 31 thereby enabling the protection wire 33 attached on the insulation member 31 to be prevented from being in contact with other electrical conduction portion of the circuit board 2, the two end parts 331, 332 of the protection wire 33 are respectively and electrically connected to the two electrical conduction blocks 322 thereby enabling the protection wire 33 to be electrically connected between the two electrical conduction blocks 322; and each of the soldering parts 21 on the circuit board 2 is defined as a soldering zone.

According to the second embodiment of the present invention, the protection set 3a is adhered on the circuit board 2 with a means of surface mount technology (SMT), so the two electrical conduction blocks 322 of the protection set 3a are respectively soldered on the two soldering parts 21 of the circuit board 2.

Based on what has been disclosed above, advantages achieved by the present invention are as following: by adopting a copper wire to be formed as the protection wire 33, the protection wire 33 having a unified size can be easily manufactured, and the same result could be obtained in the annual destructive test; moreover, the protection wire 33 is firstly attached on the insulation member 31 then respectively and electrically connected to the two electrical conduction parts 32, the protection set 3, 3a having a larger force applying area shown in FIG. 3 and FIG. 4 can be formed, so the protection set 3 is able to be easily and smoothly inserted in the circuit board 2 with a manual or a mechanical means, or the protection set 3a is able to be adhered on the circuit board 2 with a surface mount means, thereby greatly lowering the production difficulty and relatively increasing the yield rate of the power socket 100 and the power extending device.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A safe power socket, including:
a main body;
a circuit board, disposed in the main body and formed with two soldering parts; and
a protection set, electrically connected to the circuit board and including an insulation member, a protection wire and two electrical conduction parts respectively connected at one location and another location of the insulation member, the protection wire being formed with two end parts respectively and electrically connected to the two electrical conduction parts, and the two electrical conduction parts of the protection set being respectively connected to the two soldering parts of the circuit board.

2. The safe power socket according to claim 1, wherein the two electrical conduction parts of the protection set are respectively adhered with the two soldering parts of the circuit board with a surface mount means.

3. The safe power socket according to claim 2, wherein each of the electrical conduction parts is formed as an electrical conduction block, the two electrical conduction blocks are respectively connected at one location and another location of the insulation member, and the two electrical conduction blocks are served to lift the insulation member.

4. The safe power socket according to claim 1, wherein the protection set is inserted in the circuit board, each of the soldering parts of the circuit board is formed as a soldering hole, each of the electrical conduction parts is formed as an electrical conduction pin corresponding to each of the soldering holes, and the two electrical conduction pins are respectively inserted in the two soldering holes.

5. The safe power socket according to claim 4, wherein one end of each of the electrical conduction pins is formed with an electrical conduction cap, the two electrical conduction caps are respectively sleeved at one location and another location of the insulation member.

6. The safe power socket according to claim 5, wherein the other ends of the two electrical conduction pins are respectively inserted in the two soldering holes of the circuit board.

7. The safe power socket according to claim 5, wherein two end parts of the protection wire are respectively and electrically connected to the two electrical conduction caps.

8. The safe power socket according to claim 4, wherein one of the two electrical conduction pins is formed with a bending part.

9. The safe power socket according to claim 1, wherein the protection wire is reeled on the insulation member.

10. The safe power socket according to claim 1, wherein the one location and the another location of the insulation member are defined at two opposite ends of the insulation member.

11. The safe power socket according to claim 1, wherein the protection wire is a copper wire.

12. A power extension device having a safe power socket, including:
a plug;
a power cable, one end thereof being electrically connected to the plug; and
a power socket, electrically connected to the other end of the power cable and including:
a main body;
a circuit board, disposed in the main body and formed with two soldering parts; and
a protection set, electrically connected to the circuit board and including an insulation member, a protection wire and two electrical conduction parts respectively connected at one location and another location of the insulation member, the protection wire being formed with two end parts respectively and electrically connected to the two electrical conduction parts, the two electrical conduction parts of the protection set are respectively connected to the two soldering parts of the circuit board.

13. The power extension device having the safe power socket according to claim 12, wherein the power socket is installed with a socket unit.

14. The power extension device having the safe power socket according to claim 12, wherein the power socket is installed with a plurality of socket units.

15. The power extension device having the safe power socket according to claim 12, wherein the two electrical conduction parts of the protection set are respectively adhered with the two soldering parts of the circuit board with a surface mount means.

16. The power extension device having the safe power socket according to claim 15, wherein each of the electrical conduction parts is formed as an electrical conduction block, the two electrical conduction blocks are respectively connected at one location and another location of the insulation member, and the two electrical conduction blocks are served to lift the insulation member.

17. The power extension device having the safe power socket according to claim 12, wherein the protection set is inserted in the circuit board, each of the soldering parts of the circuit board is formed as a soldering hole, each of the electrical conduction parts of the protection set is formed as an electrical conduction pin corresponding to each of the soldering holes, and the two electrical conduction pins are respectively inserted in the two soldering holes.

18. The power extension device having the safe power socket according to claim 17, wherein one end of each of the electrical conduction pins is formed with an electrical conduction cap, the two electrical conduction caps are respectively sleeved at one location and another location of the insulation member.

19. The power extension device having the safe power socket according to claim 18, wherein the other ends of the two electrical conduction pins are respectively inserted in the two soldering holes of the circuit board.

20. The power extension device having the safe power socket according to claim 18, wherein two end parts of the protection wire are respectively and electrically connected to the two electrical conduction caps.

21. The power extension device having the safe power socket according to claim 17, wherein one of the two electrical conduction pins is formed with a bending part.

22. The power extension device having the safe power socket according to claim 12, wherein the protection wire is reeled on the insulation member.

23. The power extension device having the safe power socket according to claim 12, wherein the one location and the another location of the insulation member are defined at two opposite ends of the insulation member.

24. The power extension device having the safe power socket according to claim 12, wherein the protection wire is a copper wire.
